(19) United States
(12) Patent Application Publication
(10) Pub. No.: US 2013/0082368 A1
(43) Pub. Date: Apr. 4, 2013

(54) EMI SHIELDED SEMICONDUCTOR PACKAGE AND EMI SHIELDED SUBSTRATE MODULE

(71) Applicant: Samsung Electronics Co., Ltd., Suwon-Si (KR)

(72) Inventors: Tae-hoon KIM, Seongnam-si (KR); Young-lyong KIM, Gunpo-si (KR); Hyeong-seob KIM, Cheonan-si (KR); Kil-soo KIM, Hwaseong-si (KR)

(73) Assignee: SAMSUNG ELECTRONICS CO., LTD., Suwon-Si (KR)

(21) Appl. No.: 13/632,215

(22) Filed: Oct. 1, 2012

(30) Foreign Application Priority Data
Sep. 30, 2011 (KR) 1020110100033

(51) Int. Cl. H01L 23/552

(52) U.S. Cl. 257/659; 257/E23.114

(57) ABSTRACT

An EMI shielded semiconductor package includes a semiconductor package and an EMI shield layer formed on at least a part of a surface of the EMI shielded semiconductor package. The EMI shield layer includes a matrix layer; a metal layer positioned on the matrix layer; and a first seed particle positioned in an interface between the matrix layer and the metal layer. Unlike a conventional shielding process that is performed for a device level, a shielding process may be performed for a mounting substrate level, and thus the semiconductor package and the substrate module may be manufactured with high-productivity at low costs in a short period of time.

### CROSS-REFERENCE TO RELATED APPLICATIONS

This application claims the benefit of Korean Patent Application No. 10-2011-0100033, filed on Sep. 30, 2011, in the Korean Intellectual Property Office, the disclosure of which is incorporated herein in its entirety by reference.

### BACKGROUND

Example embodiments of the inventive concepts relate to an electromagnetic interference (EMI) shielded semiconductor package and/or an EMI shielded substrate module. For example, example embodiments of the inventive concepts relate to a semiconductor package and/or a substrate module that may be manufactured with high-productivity at low costs in a short period of time.

In order to protect users of electronic products from electromagnetic waves generated during use of the electronic products, many countries recommend require EMI shielding applied to semiconductor electronic devices. A conventional EMI shielding product has many limitations in terms of a manufacturing process of the EMI shielding product and durability is low. In addition, manufacturing costs are high, productivity of the EMI shielding product is very low, and an EMI shielding effect is low.

### SUMMARY

At least one example embodiment of the inventive concepts provide an EMI shielded semiconductor package that may be manufactured with high-productivity at low costs in a short period of time.

At least one example embodiment of the inventive concepts provide an EMI shielded substrate module that may be manufactured with high-productivity at low costs in a short period of time.

According to an example embodiment of the inventive concepts, there is provided an electromagnetic interference (EMI) shielded semiconductor package including: a semiconductor package; and an EMI shield layer on at least a part of a surface of the EMI shielded semiconductor package, wherein the EMI shield layer includes: a matrix layer; a metal layer on the matrix layer; and a first seed particle in an interface between the matrix layer and the metal layer.

The first seed particle may include a core particle and a surface modifying layer coated on at least a part of the core particle. The surface modifying layer may be between the core particle and the matrix layer. A diameter of the first seed particle may be in a range between 2 and 80 μm.

The surface modifying layer may include at least one of a polymer containing a thiol (—SH) group, a silane-based compound containing an alkoxy group with 1 to 10 carbon atoms, acetylacetone, and a mixture thereof. The core particle may be at least one of a metal and metal oxide.

The EMI shielded semiconductor package may further include a second seed particle in the matrix layer. The second seed particle may include a core particle and a surface modifying layer, and the surface modifying layer of the second seed particle substantially may coat the entire surface of the core particle of the second seed particle.

The semiconductor package may include a top surface and a side surface, and the EMI shield layer may be on at least a part of the top surface and the side surface.

According to another example embodiment of the inventive concepts, there is provided an electromagnetic interference (EMI) shielded substrate module comprising: a substrate; a semiconductor package on the substrate; and an EMI shield layer on at least a part of surfaces of the substrate and the semiconductor package, wherein the EMI shield layer comprises: a matrix layer; a metal layer on the matrix layer; and a first seed particle in an interface between the matrix layer and the metal layer.

The substrate may include a ground electrode, and the metal layer is electrically connected to the ground electrode. The matrix layer may be configured to expose at least one of at least a portion of the ground electrode and at least a portion of a wiring pattern that is electrically connected to the ground electrode, and the metal layer may contact at least one of the at least a portion of the ground electrode and the at least a portion of a wiring pattern that is electrically connected to the ground electrode that is exposed by the matrix layer.

The matrix layer may include a hole penetrating the matrix layer, and at least one of the at least a portion of the ground electrode and the at least a portion of a wiring pattern that is electrically connected to the ground electrode may be exposed through the hole.

Alternatively, the metal layer may extend to an external wall of the matrix layer to be electrically connected to the ground electrode or the wiring pattern electrically connected to the ground electrode.

According to an example embodiment of the inventive concepts, there is provided an electromagnetic interference (EMI) shield including an EMI shield layer including: a matrix layer including a plurality of seed particles; and a metal layer on the matrix layer, an interface between the matrix layer and the metal layer including at least one of the plurality of seed particles.

The at least one of the plurality of seed particles may include a core particle and a surface modifying layer coated on at least a part of the core particle. The surface modifying layer may be between the core particle and the matrix layer.

The surface modifying layer may include at least one of a polymer containing a thiol (—SH) group, a silane-based compound containing an alkoxy group with 1 to 10 carbon atoms, acetylacetone, and a mixture thereof.

### BRIEF DESCRIPTION OF THE DRAWINGS

Example embodiments of the inventive concepts will be more clearly understood from the following detailed description taken in conjunction with the accompanying drawings. FIGS. 1-5C represent non-limiting, example embodiments as described herein.

FIG. 1 is a side cross-sectional view of a semiconductor package according to an example embodiment of the inventive concepts;

FIG. 2 is a partial cross-sectional view for describing a relationship between core particles and a metal layer according to an example embodiment of the inventive concepts;

FIG. 3 is a side cross-sectional view of a substrate module according to an example embodiment of the inventive concepts;

FIG. 4 is a side cross-sectional view of a substrate module according to another example embodiment of the inventive concepts; and

FIGS. 5A to 5C are side cross-sectional views sequentially showing a method of manufacturing a substrate module according to an example embodiment of the inventive concepts.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments of the inventive concepts will now be described more fully with reference to the accompanying drawings, in which some example embodiments of the inventive concepts are shown. The inventive concepts may, however, be embodied in many different forms by one of ordinary skill in the art without departing from the technical teaching of the inventive concepts. Particular structural and functional description of example embodiments of the inventive concepts are provided in descriptive sense only; various changes in form and details may be made therein and thus should not be construed as being limited to the example embodiments set forth herein. As the inventive concepts are not limited to the example embodiments described in the present description, it should be understood that the inventive concepts include every kind of variation examples or alternative equivalents included in the spirit and scope of the inventive concepts.

In the present description, terms such as ‘first’, ‘second’, etc. are used to describe various elements. However, it is obvious that the elements should not be defined by these terms. The terms are used only for distinguishing one element from another element. For example, a first element could be termed a second element, and similarly, a second element may be termed a first element, without departing from the teaching of the inventive concepts.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms ‘a’, ‘an’, and ‘the’ are intended to include the plural forms as well, unless the context clearly indicates otherwise. It will be further understood that the terms ‘includes,’ including,“comprises” and/or ‘comprising’, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concepts belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. As used herein, the term ‘and/or’ includes any and all combinations of one or more of the associated listed items. Expressions such as ‘at least one of’, when preceding a list of elements, modify the entire list of elements and do not modify the individual elements of the list.

FIG. 1 is a side cross-sectional view of a semiconductor package 100 according to an example embodiment of the inventive concepts. Referring to FIG. 1, an EMI shield layer 120 may be formed on at least a part of a surface of the semiconductor package 110. The EMI shield layer 120 may be formed on at least a part of an upper surface of the semiconductor package 110. The EMI shield layer 120 may be formed on at least a part of a side surface of the semiconductor package 110.

The semiconductor package 110 may be a chip scale package (CSP), a wafer level package (WLP), a ball grid array (BGA) package, a pin grid array (PGA) package, a flip chip package, a through hole package, a direct chip attach (DCA) package, a quad flat package (QFP), a quad flat no-lead (QFN) package, a dual in-line package (DIP), a single in-line package (SIP), a zigzag in-line package (ZIP), a tape carrier package (TCP), a multi-chip package (MCP), a small outline package (SOP), a through silicon via (TSV), or the like, but example embodiments of the inventive concepts are not limited thereto.

The EMI shield layer 120 may include a matrix layer 121, a metal layer 129 positioned on the matrix layer 121, and a plurality of first seed particles 123 positioned in an interface between the matrix layer 121 and the metal layer 129.

The metal layer 129 may be formed of copper (Cu), nickel (Ni), gold (Au), silver (Ag), platinum (Pt), cobalt (Co), titanium (Ti), chrome (Cr), zirconium (Zr), molybdenum (Mo), ruthenium (Ru), hafnium (Hf), tungsten (W), rhenium (Re), or the like, but example embodiments of the inventive concepts are not limited thereto. A thickness of the metal layer 129 may be in a range between about 0.1 and about 1000 μm, but example embodiments of the inventive concepts are not limited thereto.

The matrix layer 121 may be formed between the metal layer 129 and the semiconductor package 110. The matrix layer 121 may be formed of an arbitrary polymer, but example embodiments of the inventive concepts are not limited thereto. The matrix layer 121 may be formed of, for example, an epoxy resin, a urethane resin, a polyimide resin, an acryl resin, a polyolefin resin, or the like.

A polymer used to form the matrix layer 121 may have a weight average molecular weight (MW) in a range, for example, between about 5,000 and about 500,000. The MW may be a value obtained by using gel permeation chromatography (GPC). The GPC may use, for example, tetrahydrofuran (THF) as a solvent at a flow rate of about 1 ml/minute and may use Shodex KF-800 series as a column.

Each of the first seed particles 123 may include a core particle 123a and a surface modifying layer 123b. The surface modifying layer 123b may be coated on at least a part of a surface of the core particle 123a. As shown in FIG. 1, the first seed particles 123 positioned in the interface between the matrix layer 121 and the metal layer 129 mainly include the surface modifying layer 123b in a portion contacting the matrix layer 121. In FIG. 1, although the surface modifying layer 123b is positioned in an area of the matrix layer 121, the surface modifying layer 123b may partially extend into the metal layer 129 along the surface of the core particle 123a.

In FIG. 1, although the surface modifying layer 123b is interposed between the core particle 123a and the matrix layer 121 and thus the core particle 123a does not directly contact the matrix layer 121, the surface modifying layer 123b may not be interposed between the core particle 123a and the matrix layer 121 for a portion of the surface of the core particle 123a. As a result, the core particle 123a may directly contact the matrix layer 121 at the portion of the surface of the core particle 123a.

The core particle 123a may be a metal particle or a metal oxide particle. A size of the core particle 123a may be in a range between about 0.1 and about 70 μm. A metal for forming the core particle 123a may be, for example, Cu, Ni, Au, Ag, Pt, Co, Ti, Cr, Zr, Mo, Ru, Hf, W, Re, or the like, but example embodiments of the inventive concepts are not limited thereto. A metal oxide for forming the core particle 123a may be, for example, silicon oxide, titanium oxide, cerium oxide, tungsten oxide, nickel oxide, zirconium oxide, vanadium oxide, hafnium oxide, molybdenum oxide, or the like, but example embodiments of the inventive concepts are not limited thereto.

The surface modifying layer 123b may be formed of an arbitrary material that may be combined with the core particle 123a through ion bonding or coordinate bonding. For example, a material for forming the surface modifying layer 123b may include a silane group, a silanol group, a thiol group, a carboxyl group, an amino group, an ammonium group, a nitro group, a hydroxyl group, a carbonyl group, a sulfonic acid group, sulfonium group, an oxazoline group, a pyrrolidone group, a nitrile group, an alkoxy group, or the like. A material for forming the surface modifying layer 123b may be combined with the core particle 123a through the above-described functional groups.

The surface modifying layer 123b is an organic compound including any of the functional groups described above, but example embodiments of the inventive concepts are not limited thereto. For example, a material for forming the surface modifying layer 123b may be (un)saturated hydrocarbon, aromatic hydrocarbon, (un)saturated thiol, aromatic thiol, (un)saturated fatty acid, aromatic carboxylic acid, (un)saturated ketone, aromatic ketone, (un)saturated alcohol, aromatic alcohol, (un)saturated amine, aromatic amine, a silalane-based or siloxane-based compound, derivatives thereof, a product generated due to condensation of the above-described materials, or a polymer derived from the above-described materials. In this regard, the term ‘(un)saturated’ refers to ‘saturated’ or ‘unsaturated’.

The condensation product or the polymer may be, for example, polyolefin such as polyethylene, polypropylene, or polybutadiene, polyether such as olyethyleneglycol or polypropleneglycol, polystyrene, poly(meth)acrylate, poly(meth)acrylic ester, polyvinylalcohol, polyvinylester, phenol resin, melamine resin, epoxy resin, silicon(silicone) resin, polyimide resin, polyurethane resin, teflon resin, acrylonitrile-styrene resin, styrene-butadiene resin, polyamide resin, polycarbonate resin, polyacetal resin, polyether sulfone, polyphenylene oxide, or the like.

Alternatively, the surface modifying layer 123b may be formed of a silalane-based compound containing an alkoxy group with 1 to 10 carbon atoms, acetylacetone, or the like. Alternatively, the surface modifying layer 123b may be formed of a compound of the above-described materials.

Referring to FIG. 1, the semiconductor package 100 may further include a plurality of second seed particles 125 inside the matrix layer 121. Each of the second seed particles 125 may include a core particle 125a and a surface modifying layer 125b coated on at least a part of a surface of the core particle 125a. The core particle 125a is substantially the same as the above-described core particle 123a, and thus a detailed description thereof will be omitted. Also, the surface modifying layer 125b is substantially the same as the above-described surface modifying layer 123b, and thus a detailed description thereof will be omitted.

In FIG. 1, although the surface modifying layer 125b is substantially coated on the entire surface of the core particle 125a, example embodiments of the inventive concepts are not limited thereto. The surface modifying layer 125b may be coated on at least a part of the surface of the core particle 125a.

Diameters of the first seed particles 123 or the second seed particles 125 may be in a range between about 2 and about 80 μm. Both the first seed particles 123 and the second seed particles 125 may not have a complete spherical shape. The longest distance from among distances between two points in the first seed particles 123 or the second seed particles 125 may be in a range between about 2 and about 80 μm.

When the semiconductor package 100 of FIG. 1 is mounted on a substrate, the metal layer 129 of the EMI shield layer 120 may be formed to contact a ground terminal (not shown) on the substrate. Alternatively, the semiconductor package 110 may include a ground terminal (not shown), and the metal layer 129 of the EMI shield layer 120 may be formed to contact the ground terminal of the semiconductor package 110.

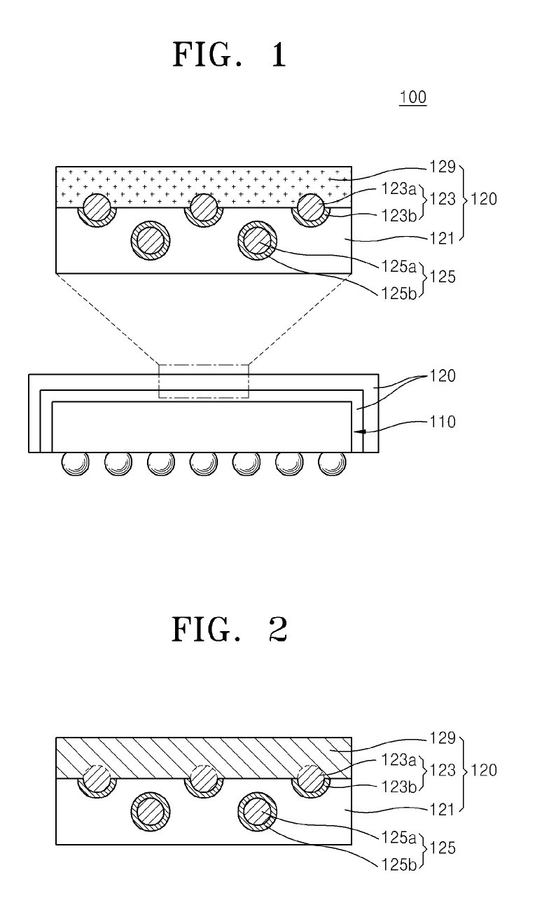

FIG. 2 is a partial cross-sectional view for describing a relationship between the core particle 123a and the metal layer 129 according to an example embodiment of the inventive concepts. Referring to FIG. 2, when the core particle 123a of the first seed particles 123 is formed of a metal, the metal may be the same as or different from that of the metal layer 129. When the core particles 123a are formed of metal different from that of the metal layer 129, an interface between the core particles 123a and the metal layer 129 may not be clearly observed.

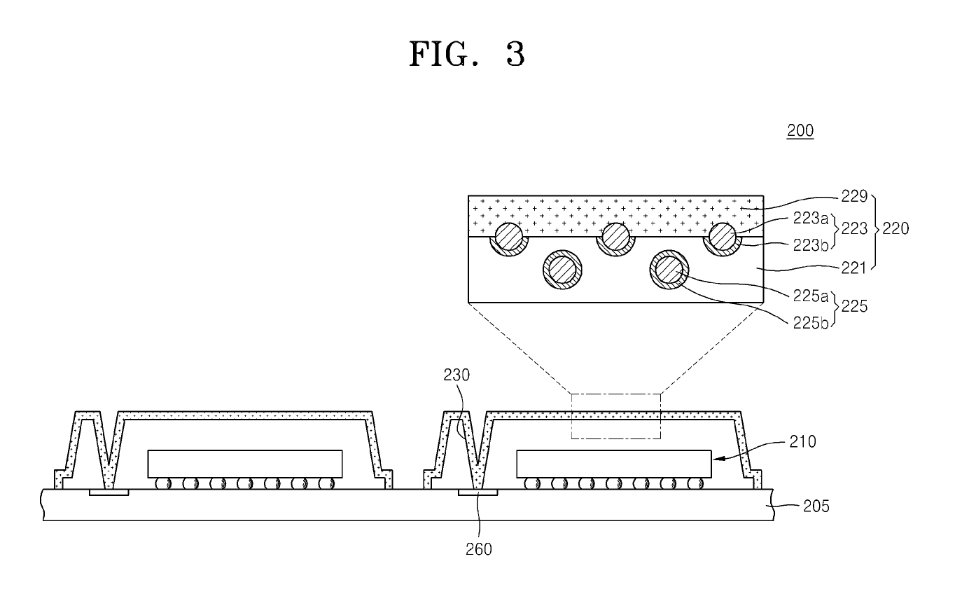

FIG. 3 is a side cross-sectional view of an EMI shielded substrate module 200 according to an example embodiment of the inventive concepts. Referring to FIG. 3, a plurality of semiconductor packages 210 may be mounted on a substrate 205, and an EMI shield layer 220 may be formed on at least a part of the semiconductor packages 210 and the substrate 205.

The EMI shield layer 220 may include a matrix layer 221, a metal layer 229, and a plurality of first seed particles 223 positioned in an interface between the matrix layer 221 and the metal layer 229. Each of the first seed particles 223 may include a core particle 223a and a surface modifying layer 223b. A plurality of second seed particles 225 may be included in the matrix layer 221, and each of the second seed particles 225 may include a core particle 225a and a surface modifying layer 225b. A major structure of the EMI shield layer 220 is the same as that of the EMI shield layer 120 of FIG. 1, and thus a detailed description thereof will be omitted.

The substrate 205 may be a printed circuit board (PCB) including a plurality of ground electrodes 260, or may be any other substrate such as a wafer, a glass substrate, or the like. The plurality of semiconductor packages 210 may be mounted on the substrate 205. Wiring lines for electrical connection may be disposed on a top surface of the substrate 205 or inside the substrate 205.

The substrate 205 may include the ground electrodes 260. The matrix layer 221 may be formed to expose the ground electrodes 260 or at least a part of wiring patterns that are electrically connected to the ground electrodes 260.

For example, the matrix layer 221 may include a plurality of holes 230 that penetrate the matrix layer 221, and the metal layer 229 may extend into the holes 230 to be electrically connected to the ground electrodes 260. In FIG. 3, although the ground electrodes 260 are exposed by the holes 230, the holes 230 may instead expose the wiring patterns electrically connected to the ground electrodes 260. The metal layer 229 may extend into the holes 230 to be electrically connected to the wiring patterns electrically connected to the ground electrodes 260.

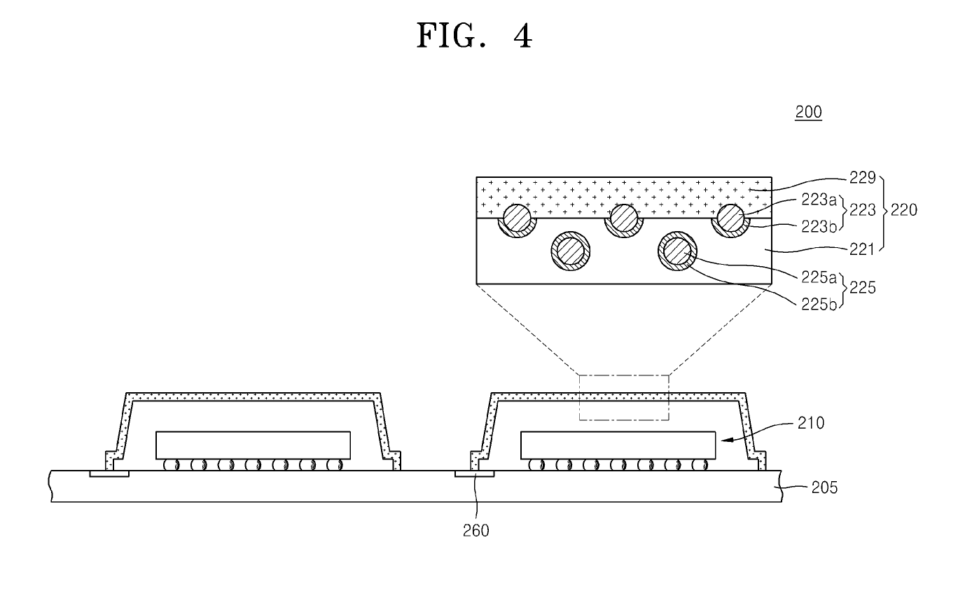

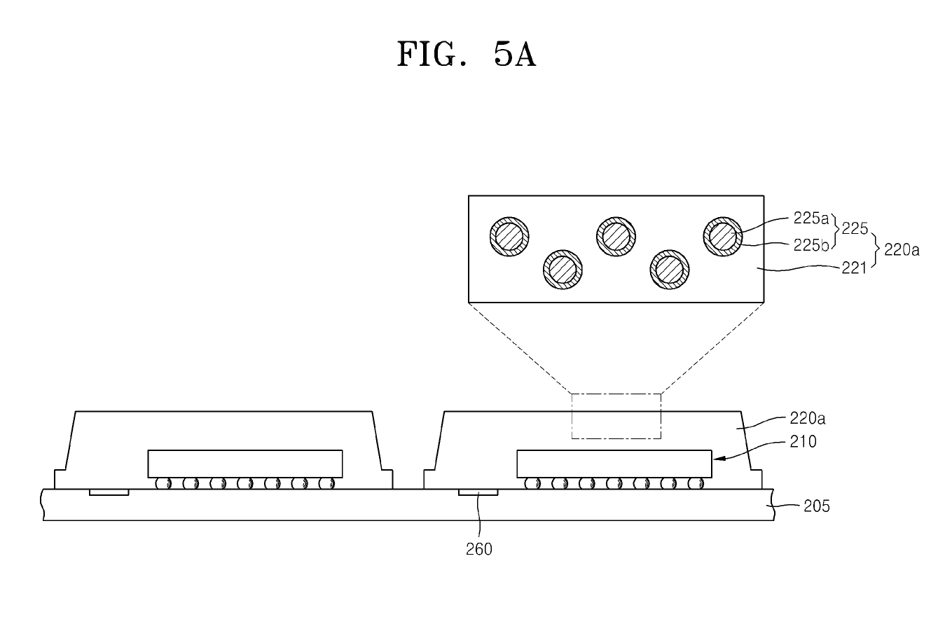

FIG. 4 is a side cross-sectional view of the EMI shielded substrate module 200 according to another example embodiment of the inventive concepts. Referring to FIG. 4, the metal layer 229 may extend to an external wall of the matrix layer 221 to be electrically connected to the ground electrodes 260. In FIG. 4, although the metal layer 229 is electrically connected to the ground electrodes 260, the metal layer 229 may be electrically connected to the wiring patterns electrically connected to the ground electrodes 260.

Accordingly, since there is no need to form the holes 230 exposing the ground electrodes 260 inside the matrix layer 221 as shown in FIG. 3, the whole manufacturing process may become simple.

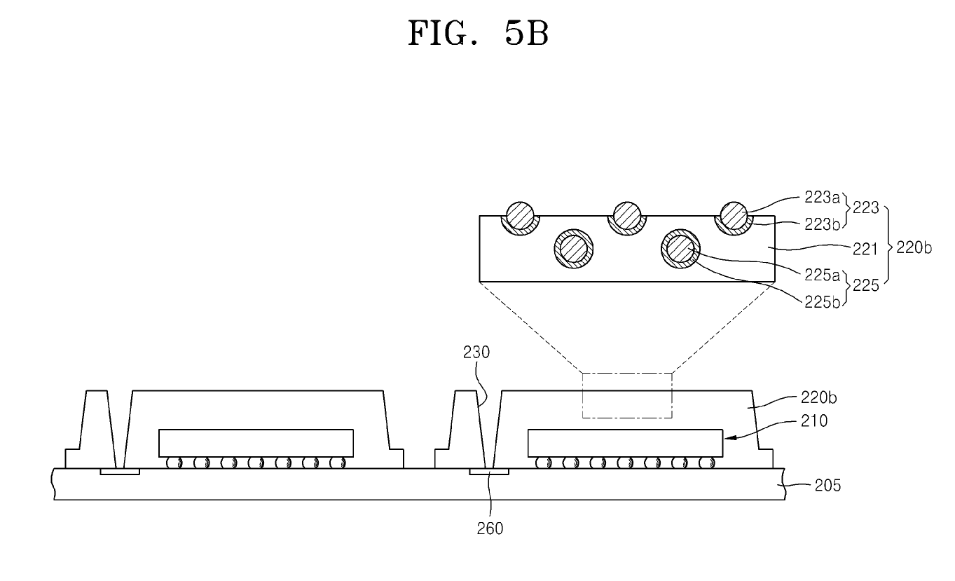

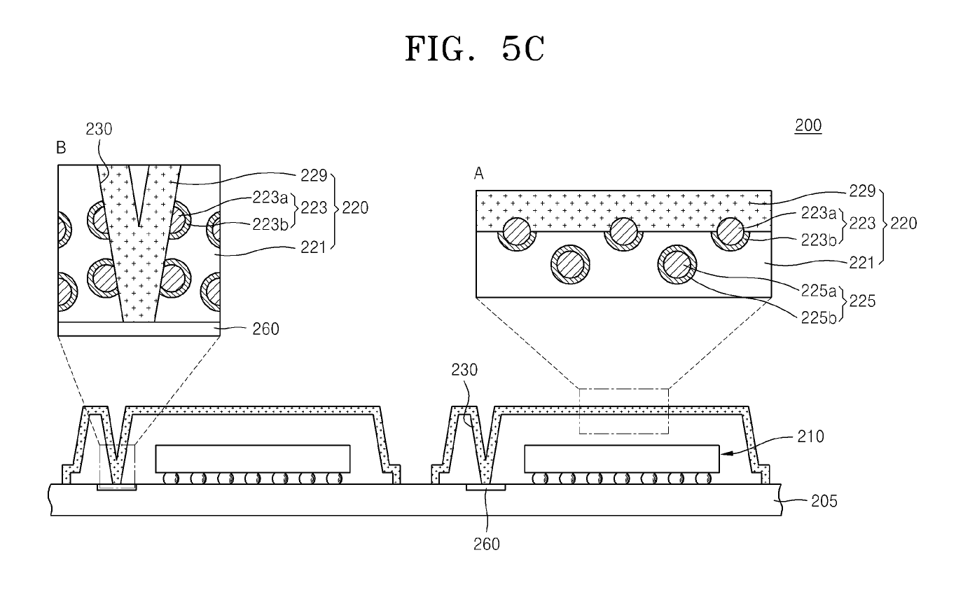

FIGS. 5A to 5C are side cross-sectional views sequentially showing a method of manufacturing the EMI shielded substrate module 200 according to an example embodiment of the inventive concepts.

Referring to FIG. 5A, after at least one semiconductor package 210 is mounted on the substrate 205, a matrix material layer 220a is formed to cover the semiconductor package 210. The matrix material layer 220a may be formed by forming a matrix composition, disposing the matrix composition around the semiconductor package 210, and then curing the matrix composition. The matrix composition may be disposed around the semiconductor package 210 by using a mold.

The matrix composition may further include the first seed particles 225. The first seed particles 225 may be uniformly distributed inside the matrix composition with a proper concentration. The concentration of the first seed particles 225 may be in a range between about 1 and about 15 wt % with respect to the entire weight of the matrix composition. If the concentration of the first seed particles 225 is too low, the metal layer 229 (FIG. 5C) may not be effectively formed. On the other hand, if the concentration of the first seed particles 225 is too high, processability of the matrix composition may be decreased.

A method of obtaining the first seed particles 225 is not particularly limited, and the first seed particles 225 may be obtained by using a particle surface modifying method that is known in the art. In other words, the first seed particles 225 may be obtained by using an arbitrary method including combining an organic compound with a surface of a metal particle or a metal oxide particle through a functional group. For example, the arbitrary method may be a method of grafting an organic compound onto a surface of a metal particle or a metal oxide particle, a method of combining an organic compound including a functional group having a bonding property with respect to a specific metal component with a surface of a metal particle or a metal oxide particle, a method of coating a surface of a metal with an organic compound precursor and then bridging and/or polymerizing the organic compound precursor, or the like.

The matrix composition may be cured by heat curing, ultra-violet (UV) curing, or the like well known in the art.

Referring to FIG. 5B, the core particle 223a inside the first seed particles 223 is exposed by de-smearing the matrix material layer 220a and thus a matrix material layer 220b is obtained. The de-smearing may be performed through soft etching using plasma or wet de-smearing using a de-smearing solution such as potassium permanganate or sodium permanganate. When the de-smearing is performed through wet de-smearing, the matrix material layer 220b may be soaked in a de-smearing solution at an increased temperature for a given period of time. For example, a de-smearing temperature may be in a range between about 60 and about 90° C. A de-smearing time may be in a range between about 1 and about 10 minutes.

As such, the core particles 223a may be exposed by performing de-smearing as shown in FIG. 5B.

The holes 230 may be formed in the matrix material layer 220b to expose the ground electrodes 260. The holes 230 may be formed, for example, by laser processing. In FIG. 5B, although the holes 230 are formed to expose the ground electrodes 260, the holes 230 may be formed to expose conductive patterns electrically connected to the ground electrodes 260.

Furthermore, although the holes 230 are formed after performing de-smearing, the de-smearing may instead be performed after forming the holes 230.

Referring to FIG. 5C, the metal layer 229 is formed by performing electroless plating on the entire surface of the matrix layer 221 by using the core particles 223a as seeds. The metal layer 229 formed by electroless plating may include, for example, Cu, Ni, Au, Ag, Pt, Co, Ti, Cr, Zr, Mo, Ru, Hf, W, Re, or the like. Alternatively, the electroless plating may be continuously performed until the metal layer 229 is completely formed or may be performed until a seed layer having a small thickness is formed. In the latter case, in order to obtain the metal layer 229 having a desired thickness, electroplating may be performed after performing the electroless plating.

In FIG. 5C, a part ‘B’ shows the metal layer 229 formed in the hole 230. Referring to the part ‘B’ of FIG. 5C, since the holes 230 are formed by performing de-smearing and then using a laser, the core particles 223a contacting the hole 230 are destroyed and damaged.

Processing using a laser is not performed and only de-smearing is performed on a top surface of the matrix layer 221 of a part ‘A’, and thus the core particles 223a may be exposed without being damaged.

As described above, the de-smearing may be performed after forming the holes 230, and the damaged core particles 223a may be removed during the de-smearing. Accordingly, insides of the holes 230 may be exposed without damaging the core particles 223a as in the top surface of the matrix layer 221.

As described above, an EMI shield layer is formed after mounting a plurality of semiconductor packages on one substrate, and thus productivity may be increased compared to a method of forming an EMI shield layer in each semiconductor package. Since a high-priced metal material may be effectively used, manufacturing costs may be reduced.

While the inventive concepts have been particularly shown and described with reference to some example embodiments thereof, it will be understood that various changes in form and details may be made therein without departing from the spirit and scope of the following claims.

What is claimed is:

1. An electromagnetic interference (EMI) shielded semiconductor package comprising:
a semiconductor package; and
an EMI shield layer on at least a part of a surface of the EMI shielded semiconductor package,
wherein the EMI shield layer includes,
a matrix layer;
a metal layer on the matrix layer; and
a first seed particle in an interface between the matrix layer and the metal layer.

2. The EMI shielded semiconductor package of claim 1, wherein the first seed particle includes a core particle and a surface modifying layer coated on at least a part of the core particle.

3. The EMI shielded semiconductor package of claim 2, wherein the surface modifying layer is between the core particle and the matrix layer.

4. The EMI shielded semiconductor package of claim 2, wherein the surface modifying layer includes at least one of a polymer containing a thiol (—SH) group, a silane-based compound containing an alkoxy group with 1 to 10 carbon atoms, acetylacetone and a mixture thereof.

5. The EMI shielded semiconductor package of claim 2, wherein the core particle is at least one of a metal and metal oxide.

6. The EMI shielded semiconductor package of claim 2, further comprising:
a second seed particle in the matrix layer.

7. The EMI shielded semiconductor package of claim 6, wherein the second seed particle includes a core particle and a surface modifying layer and the surface modifying layer of the second seed particle substantially coats the entire surface of the core particle of the second seed particle.

8. The EMI shielded semiconductor package of claim 1, wherein a diameter of the first seed particle is in a range between 2 and 80 μm.

9. The EMI shielded semiconductor package of claim 1, wherein the semiconductor package includes a top surface and a side surface and the EMI shield layer is on at least a part of the top surface and the side surface.

10. An electromagnetic interference (EMI) shielded substrate module comprising:
a substrate;
a semiconductor package on the substrate; and
an EMI shield layer on at least a part of surfaces of the substrate and the semiconductor package,
wherein the EMI shield layer includes,
a matrix layer;
a metal layer on the matrix layer; and
a first seed particle in an interface between the matrix layer and the metal layer.

11. The EMI shielded substrate module of claim 10, wherein the substrate includes a ground electrode and the metal layer is electrically connected to the ground electrode.

12. The EMI shielded substrate module of claim 11, wherein the matrix layer is configured to expose at least one of at least a portion of the ground electrode and at least a portion of a wiring pattern that is electrically connected to the ground electrode, and the metal layer contacts at least one of the at least a portion of the ground electrode and the at least a portion of a wiring pattern that is electrically connected to the ground electrode that is exposed by the matrix layer.

13. The EMI shielded substrate module of claim 12, wherein the matrix layer includes a hole penetrating the matrix layer and at least one of the at least a portion of the ground electrode and the at least a portion of a wiring pattern that is electrically connected to the ground electrode is exposed through the hole.

14. The EMI shielded substrate module of claim 12, wherein the metal layer extends to an external wall of the matrix layer to be electrically connected to at least one of the ground electrode and the wiring pattern electrically connected to the ground electrode.

15. The EMI shielded substrate module of claim 10, wherein a plurality of semiconductor packages are on the substrate.

16. An electromagnetic interference (EMI) shielded semiconductor package comprising:
a matrix layer including a plurality of seed particles; and
a metal layer on the matrix layer, an interface between the matrix layer and the metal layer including at least one of the plurality of seed particles.

17. The EMI shielded semiconductor package of claim 16, wherein the at least one of the plurality of seed particles includes at least one core particle and at least one surface modifying layer coated on at least a part of the core particle.

18. The EMI shielded semiconductor package of claim 17, wherein the at least one surface modifying layer is between the at least one core particle and the matrix layer.

19. The EMI shielded semiconductor package of claim 17, wherein the at least one surface modifying layer includes at least one of a polymer containing a thiol (—SH) group, a silane-based compound containing an alkoxy group with 1 to 10 carbon atoms, acetylacetone and a mixture thereof.
